(19) United States
(12) Patent Application Publication
(10) Pub. No.: US 2022/0351037 A1
(43) Pub. Date: Nov. 3, 2022

(54) METHOD AND SYSTEM FOR SPECTROSCOPIC PREDICTION OF SUBSURFACE PROPERTIES USING MACHINE LEARNING

(71) Applicant: Saudi Arabian Oil Company, Dhahran (SA)

(72) Inventors: Weichang Li, Katy, TX (US); Damian Pablo San Roman Alerigi, Al- Khobar (SA)

(21) Appl. No.: 17/731,691

(22) Filed: Apr. 28, 2022

Related U.S. Application Data
(60) Provisional application No. 63/182,068, filed on Apr. 30, 2021.

(51) Int. Cl. G06N 3/08; G06F 30/27

(52) U.S. Cl. CPC G06N 3/08; G06F 30/27

(57) ABSTRACT

A computer-implemented method includes: accessing a plurality of geo-exploration data from a first drilling site, wherein the plurality of geo-exploration data include spectroscopic infra-red (IR) data and well logs, wherein at least portions of the plurality of geo-exploration data are based on measurements of core samples taken from the first drilling site; based on, at least in part, the plurality of geo-exploration data, training a set of deep learning models, each deep learning model comprising multiple layers and configured to predict one or more geological formation properties; applying the set of deep learning models to newly received geo-exploration data that also includes spectroscopic IR data; and predicting the one or more geological formation properties based on, at least in part, the newly received geo-exploration data.

### RELATED APPLICATION

This application claims benefit of U.S. Provisional Application No. 63/182,068 under 35 USC § 119(e), the entirety of which is incorporated by reference.

### TECHNICAL FIELD

This disclosure generally relates to rock characterization and classification for geo-exploration.

### BACKGROUND

Rock, in geology, refers to naturally occurring and coherent aggregate of one or more minerals. Such aggregates constitute the basic unit of which the solid Earth is composed. The aggregates typically form recognizable and mappable volumes. Characterization and classification of rocks can reveal insights about the layered formation, including fluid saturation, of the solid Earth during a drilling operation in the context of gas and oil exploration.

### SUMMARY

In one aspect, some implementations provide a computer-implemented method that includes: accessing a plurality of geo-exploration data from a first drilling site, wherein the plurality of geo-exploration data include spectroscopic infra-red (IR) data, wherein at least portions of the plurality of geo-exploration data are based on measurements of core samples taken from the first drilling site; based on, at least in part, the plurality of geo-exploration data including the spectroscopic IR data, training a set of deep learning models, each deep learning model comprising multiple layers and configured to predict one or more geological formation properties; applying the set of deep learning models to newly received geo-exploration data that also includes spectroscopic IR data; and predicting the one or more geological formation properties based on, at least in part, the newly received geo-exploration data.

Implementations may include one or more of the following features.

The spectroscopic IR data may include Fourier Transform Infrared Spectroscopy (FTIR) data of core samples at the drilling site, and wherein the newly received geo-exploration data are from a second drilling site different from the first drilling site.

The set of deep learning models may include a first deep learning model configured to predict a rock type of the core samples, and wherein training the first deep learning model includes training based on, at least in part, the FTIR data of the core samples from the first drilling site. The set of deep learning models may include a second deep learning model configured to predict a geomechanical property of the core samples, and wherein training the second deep learning model includes training based on, at least in part, the FTIR data of the core samples at first the drilling site. The set of deep learning models may include a third deep learning model configured to predict a sonic velocity of the core samples, and wherein training the third deep learning includes training based on, at least in part, the FTIR data of the core samples at the first drilling site. The set of deep learning models may include a fourth deep learning model configured to predict a permeability of the core samples, and wherein training the fourth deep learning includes training based on, at least in part, the FTIR data of the core samples at the first drilling site.

The method may further include: validating the set of deep learning models by cross correlating predicted values of the one or more geological formation properties with measured values of the one or more geological formation properties.

At least one deep learning model from the set of deep learning models may be trained predict a geological formation property with a spatial resolution that is higher than well logs in the plurality of geo-exploration data.

The set of deep learning model may each comprises a layer of one or more convolutional neural network (CNN) blocks. The layer of one or more CNN blocks may be followed by a softmax layer or a regressor layer, wherein the softmax layer may be configured to generate a classification as a geological formation property, and wherein the regressor layer may be configured to quantify a value of a geological formation property.

In another aspect, some implementations provide a computer system comprising one or more computer processors configured to perform operations of: accessing a plurality of geo-exploration data from a first drilling site, wherein the plurality of geo-exploration data include spectroscopic infra-red (IR) data, wherein at least portions of the plurality of geo-exploration data are based on measurements of core samples taken from the first drilling site; based on, at least in part, the plurality of geo-exploration data including the spectroscopic IR data, training a set of deep learning models, each deep learning model comprising multiple layers and configured to predict one or more geological formation properties; applying the set of deep learning models to newly received geo-exploration data that also includes spectroscopic IR data; and predicting the one or more geological formation properties based on, at least in part, the newly received geo-exploration data.

Implementations may include one or more of the following features.

The spectroscopic IR data may include Fourier Transform Infrared Spectroscopy (FTIR) data of core samples at the drilling site, and wherein the newly received geo-exploration data are from a second drilling site different from the first drilling site.

The set of deep learning models may include a first deep learning model configured to predict a rock type of the core samples, and wherein training the first deep learning model includes training based on, at least in part, the FTIR data of the core samples from the first drilling site. The set of deep learning models may include a second deep learning model configured to predict a geomechanical property of the core samples, and wherein training the second deep learning model includes training based on, at least in part, the FTIR data of the core samples at first the drilling site. The set of deep learning models may include a third deep learning model configured to predict a sonic velocity of the core samples, and wherein training the third deep learning includes training based on, at least in part, the FTIR data of the core samples at the first drilling site. The set of deep learning models may include a fourth deep learning model configured to predict a permeability of the core samples, and wherein training the fourth deep learning includes training based on, at least in part, the FTIR data of the core samples at the first drilling site.

The operations may further include: validating the set of deep learning models by cross correlating predicted values of the one or more geological formation properties with measured values of the one or more geological formation properties.

At least one deep learning model from the set of deep learning models may be trained predict a geological formation property with a spatial resolution that is higher than well logs in the plurality of geo-exploration data.

The set of deep learning model may each comprises a layer of one or more convolutional neural network (CNN) blocks. The layer of one or more CNN blocks may be followed by a softmax layer or a regressor layer, wherein the softmax layer may be configured to generate a classification as a geological formation property, and wherein the regressor layer may be configured to quantify a value of a geological formation property.

The details of one or more implementations of the subject matter of this specification are set forth in the description, the claims, and the accompanying drawings. Other features, aspects, and advantages of the subject matter will become apparent from the description, the claims, and the accompanying drawings.

### DESCRIPTION OF DRAWINGS

FIG. 1 illustrates an example of a system according to an implementation of the present disclosure.

FIG. 2 illustrates another example of a system according to an implementation of the present disclosure.

FIG. 3 illustrates an example of a flow chart according to an implementation of the present disclosure.

FIG. 4 illustrates an example of a system diagram according to an implementations of the present disclosure.

FIG. 5 illustrates an example of the FTIR spectrum for a set of core samples as used by some implementations of the present disclosure.

FIG. 6 shows examples of mean FTIR spectrum and standard deviation for several rock types according to some implementations of the present disclosure.

FIG. 7 shows an example of a cross plot for training data set according to some implementations of the present disclosure.

FIG. 8 shows another example of a cross plot of stiffness and logarithmic permeability for the training data set according to some implementations of the present disclosure.

FIG. 9 shows yet another example of the distribution of the number of core data for a plurality of rock types according to some implementations of the present disclosure.

FIG. 10 shows a deep learning (DL) model according to an example of an implementation of the present disclosure.

FIG. 11 shows an example of the convolutional neural network (CNN) architecture for classifying a plurality of rock types according to some implementations of the present disclosure.

FIG. 12 shows an example of the confusion matrix for classifying a plurality of rock types according to some implementations of the present disclosure.

FIG. 13 shows an example of the cross plot for predicted stiffness values and measured stiffness values for a plurality of rock types according to some implementations of the present disclosure.

FIG. 14 shows an example of the cross plot for predicted Vp values and measured Vp values for a plurality of rock types according to some implementations of the present disclosure.

FIG. 15 shows an example of the cross plot for predicted logarithmic permeability values and measured logarithmic permeability values for a plurality of rock types according to some implementations of the present disclosure.

FIG. 16 show an example of the DL model to map the coarse resolution well log data to high resolution core scale formation properties according to some implementations of the present disclosure.

FIG. 17 is a block diagram illustrating an example of a computer system used to provide computational functionalities associated with described algorithms, methods, functions, processes, flows, and procedures, according to an implementation of the present disclosure.

Like reference numbers and designations in the various drawings indicate like elements.

### DETAILED DESCRIPTION

Estimating subsurface properties at different scales and resolution can provide guidance to exploration, development, and production of energy resources and mineral deposits. The petrophysical analysis generally involves a set of multiphysics characterization based on core samples to determine the mechanical, chemical, thermal, and electromagnetic properties of subsurface matter (for example, the solids and fluids in the reservoir, casing, and wellbore). In addition, multiphysics core measurements can be performed over different core plug scales and log scales to constrain geomechanical, geological, and reservoir model building. Recent development in distributed and robotized sensors enable the acquisition of high-resolution characterization datasets of mechanical, chemical, and electromagnetic properties. Examples of such sensors or probes may include: impulse hammer geomechanical probe, hyperspectral and Fourier transform spectrometers (e.g. FTIR spectroscopy, X-Ray fluorescence (XRF), Fluorescence, Raman), Nuclear Magnetic Resonance (NMR), and acoustic transducers. These scanning tools can measure, for example, unconstrained sonic velocities and near-surface gas permeability. Such measurements can characterize the petrophysical properties at fine scale and, when combined with the data from whole core processing and well logs, can reveal log-scale variations and how the variations are related to plug scale observations. The characterizations can then be used to infer sequence stratigraphy based on correlating depositional sequence observed at many scales in the core. When integrated with other types of geophysical measurements and geological data, the inference can thus allow extrapolating the properties across the inter-well reservoir volume.

The implementations can integrate the IR reflectance data with well logs and other geophysics data from samples of well cores to assist the exploration, development and production of energy resources and mineral deposits. For example, various implementations can incorporate a machine learning (ML) algorithm and a ML model to predict, based on the spectroscopic IR reflectance data taken on site, the rock types, the geomechanical properties including the acoustic properties such as the density, compressional velocity Vp and shear velocity Vs. Assessing such geomechanical properties can be beneficial to a host of inquiries ranging from wellbore integrity to completion design. In some implementations, analyzing the IR reflectance data can enable geochemical analysis and provide a molecular characterization of rocks and fluids properties. In contrast to traditional tests that may be destructive and/or require significant time or capital investment, and may lead to sparse characterization of some physical properties, implementations can integrate the in-situ spectroscopic data (e.g., FTIR spectrum data) into one or more ML algorithms (e.g., an unsupervised ML algorithm, a supervised ML algorithm, a deep learning (DL) algorithm) to provide onsite prediction of rock type, geomechanical property, sonic velocity, permeability and other formation properties.

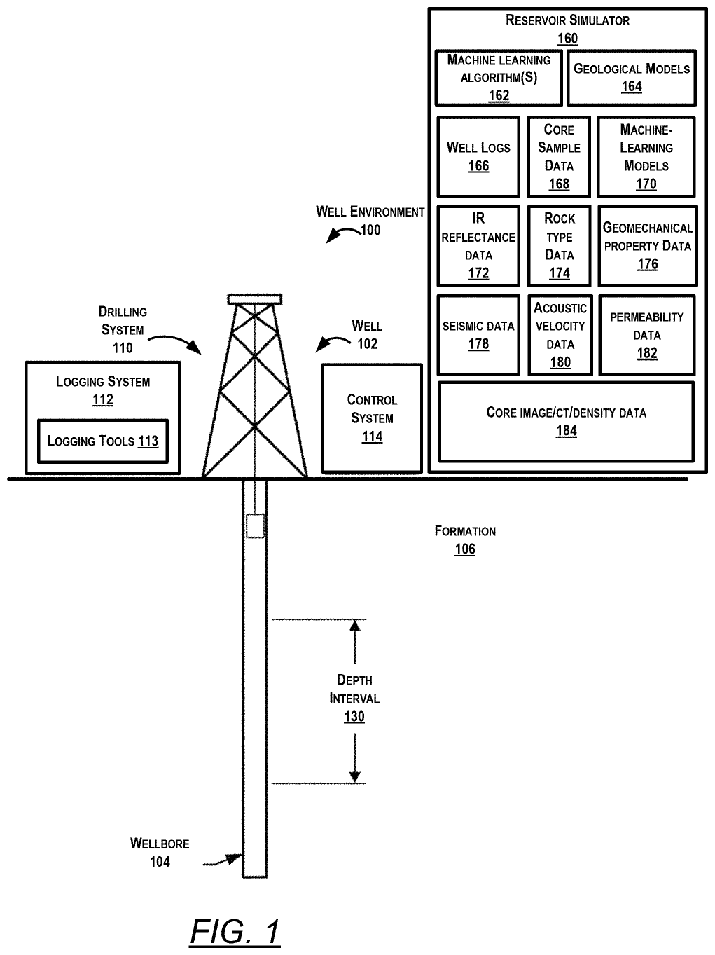

Referring to FIG. 1, a schematic diagram in accordance with some implementations of the present disclosure illustrates a well environment (100). As illustrated, well environment includes a well 102, a drilling system (110), a logging system (112), a control system (114), and a reservoir properties estimator (160).

Well 102 includes a wellbore (104) extending into a formation (106). The wellbore (104) may include a bored hole that extends from the surface into a target zone of the formation (106), such as a reservoir. The formation (106) is associated with various formation characteristics of interest, such as formation porosity, formation permeability, rock type, unconstrained sonic velocity, stiffness, resistivity, density, water saturation, total organic content, volume of kerogen, Young's modulus, Poisson's ratio and the like. Porosity may indicate how much space exists in a particular rock within an area of interest in the formation, where oil, gas, and/or water may be trapped. Rock type may indicate the lithology information for a formation within the area of interest. Unconstrained sonic velocity may indicate the compressional velocity (Vp) and shear velocity (Vs) for a formation within the area of interest. Stiffness may indicate the elasticity for a formation within the area of interest. Permeability may indicate the ability of liquids and gases to flow through the rock within the area of interest. Resistivity may indicate how strongly rock and/or fluid within the formation opposes the flow of electrical current. For example, resistivity may be indicative of the porosity of the formation and the presence of hydrocarbons. More specifically, resistivity may be relatively low for a formation that has high porosity and a large amount of water, and resistivity may be relatively high for a formation that has low porosity or includes a large amount of hydrocarbons. Water saturation may indicate the fraction of water in a given pore space.

Drilling system 110 may include a drill string, a drill bit, a mud circulation system and/or the like for use in creating the wellbore 104 into the formation 106. As illustrated, depth interval 130 may refer to the interval for placing the drill bit inside the wellbore 104.

Control system 114 may include hardware and/or software for managing drilling operations and/or maintenance operations. For example, control system 114 may include one or more programmable logic controllers (PLCs) that include hardware and/or software with functionality to control one or more processes performed by the drilling system 110. Specifically, a programmable logic controller may control valve states, fluid levels, pipe pressures, warning alarms, and/or pressure releases throughout a drilling rig. In particular, a programmable logic controller may be a ruggedized computer system with functionality to withstand vibrations, extreme temperatures, wet conditions, and/or dusty conditions, for example, around a drilling rig. Without loss of generality, the term “control system” may refer to a drilling operation control system that is used to operate and control the equipment, a drilling data acquisition and monitoring system that is used to acquire drilling process and equipment data and to monitor the operation of the drilling process, or a drilling interpretation software system that is used to analyze and understand drilling events and progress.

Logging system 112 includes one or more logging tools 113. Examples of logging tool 113 may include, an impulse hammer geomechanical probe, a hyperspectral and Fourier transform spectrometer (e.g., FTIR, XRF, Fluorescence, Raman), a NMR spectrometer, an acoustic transducer, or a resistivity logging tool. The one or more logging tools 113 may generate well logs 166, core sample data 168, IR reflectance data 172, rock type data 174, geomechanical property data 176, acoustic velocity data 180 and permeability data 182 of the formation 106. The logging tools 113 can characterize the petrophysical properties (e.g., unconstrained sonic velocities, near-surface gas permeability, etc.) at a fine scale and, when combined with the data from whole core processing and well logs, reveal log-scale variations and how the variations relate to plug scale observations. For example, the impulse hammer geomechanical probe may measure the variability of mechanical properties (e.g., geomechanical property data 176) of core samples for early stage geomechanical profiling, thereby allowing for optimized plug selection, improved core-to-log integration, and improved geomechanical rocktyping and upscaling. The impulse hammer logs measure the reduced Young's modulus (E*) by measuring the force-time response at the tip of a small instrumented sensor dropped on a core surface from a specified height and sampling interval. The measurement of reduced Young's modulus may be used to determine other elastic properties for a plurality of core samples (e.g., whole core, slabbed core, viewing slabs, and the ends of small plug samples). More specifically, the impulse hammer logs measure mechanical variations in two dimensions, and measure both elastic stiffness and hardness.

In one example, FTIR spectroscopy can generate a FTIR spectrum measures the intensity of an infrared beam after the beam passes through a rock sample. While all molecules can absorb infrared light, each type of molecule exhibits a unique absorption profile. This property can provide a unique characteristic for each molecule, which may be used to identify the molecule type. Indeed, the FTIR spectrum may be compared against a library of mineral standards to potentially reveal the mineralogy of the rock sample, which can provide rock type data 174. FTIR spectroscopy is a non-destructive alternative to conventional quantitative analysis and capable of providing fast and high resolution mapping of petrophysical properties.

In another example, a NMR logging tool may measure the NMR spectrum of hydrogen nuclei (e.g., protons) within the fluid-filled pore space of porous media (e.g., reservoir rocks). Thus, NMR logs may measure the NMR spectrum of fluids present in the pore spaces of the reservoir rocks. In so doing, NMR logs may measure both porosity and permeability (e.g., permeability data 182), as well as the types of fluids present in the pore spaces. Thus, NMR logging may be a subcategory of electromagnetic logging that responds to the presence of hydrogen protons rather than a rock matrix. Because hydrogen protons may occur primarily in pore fluids, NMR logging may directly or indirectly measure the volume, composition, viscosity, and distribution of pore fluids.

In yet another example, an acoustic configuration may measure acoustic reflection signals in response to impulses transmitted by a transmitter, which can be a transmitting transducer. The acoustic reflection signals may be picked up by a receiver, such as a hydrophone or a receiving transducer, mounted on a support for movement through the length of the well bore. The transmitter and receiver may be spaced apart by a fixed distance and as the support is moved through the well bore. The amplitudes of the received signals are correlated with the depth in the well bore to provide a log indicating the qualities (e.g., acoustic velocity data 180) of the cement bonding to the bore over the length of the well.

In still another example, a logging tool may allow measurements taken inside wellbore 104 when the tool traverses a depth interval 130 (e.g., a targeted reservoir section) of the wellbore 104. The measurements may also be performed in the laboratory on samples taken from wellbore 104. The measurements can generate well logs 166, core sample data 168, permeability data 182, and core image/CT/density data 184. The plot of the logging measurements may be a function of depth, which is referred to as a “log” or “well log”. Well logs 166 may provide depth measurements of well 102 that describe such reservoir characteristics as formation porosity, formation permeability, resistivity, density, water saturation, total organic content (TOC), volume of kerogen, Young's modulus, Poisson's ratio, and the like. The resulting logging measurements may be stored and/or processed, for example, by the control system 114, to generate corresponding well logs 166 for the well 102. A well log may include, for example, a plot of a logging response time versus true vertical depth (TVD) across the depth interval 130 of the wellbore 104.

Reservoir characteristics may be determined using a variety of different techniques. For example, certain reservoir characteristics can be determined via coring (e.g., physical extraction of rock samples) to produce core samples and/or logging operations (e.g., wireline logging, logging-while-drilling (LWD) and measurement-while-drilling (MWD)). Coring operations may include physically extracting a rock sample from a region of interest within the wellbore 104 for detailed laboratory analysis. For example, when drilling an oil or gas well, a coring bit may cut plugs (or “cores” or “core samples”) from the formation 106 and bring the plugs to the surface, and these core samples may be analyzed at the surface (e.g., in a lab) to determine various characteristics of the formation 106 at the location where the sample was obtained.

To determine porosity in the formation 106, various types of logging techniques may be used. For example, the logging system 112 may measure the speed that acoustic waves travel through rocks in the formation 106. This type of logging may generate borehole compensated (BHC) logs, which are also called sonic logs. In general, sound waves may travel faster through high-density shales than through lower-density sandstones. Likewise, density logging may also determine density measurements or porosity measurements by directly measuring the density of the rocks in the formation 106. Furthermore, neutron logging may determine porosity measurements by assuming that the reservoir pore spaces within the formation 106 are filled with either water or oil and then measuring the amount of hydrogen atoms (i.e., neutrons) in the pores. In some implementations, gamma ray logging is used to measure naturally occurring gamma radiation to characterize rock or sediment regions within a wellbore. In particular, different types of rock may emit different amounts and different spectra of natural gamma radiation. For example, gamma ray logs may distinguish between shales and sandstones/carbonate rocks because radioactive potassium may be common to shales. Likewise, the cation exchange capacity of clay within shales also results in higher absorption of uranium and thorium further increasing the amount of gamma radiation produced by shales.

The various logging techniques can also include resistivity logging, which can measure the electrical resistivity of rock or sediment in and around the wellbore 104. In particular, resistivity measurements may determine what types of fluids are present in the formation 106 by measuring how effective these rocks are at conducting electricity. Because fresh water and oil are poor conductors of electricity, fresh water and oil tend to have high resistivities. As such, resistivity measurements obtained via such logging can be used to determine corresponding reservoir water saturation (S_{W}).

Another type of logging technique includes dielectric logging. For example, dielectric permittivity may be defined as a physical quantity that describes the propagation of an electromagnetic field through a dielectric medium. As such, dielectric permittivity may describe a physical medium's ability to polarize in response to an electromagnetic field, and thus reduce the total electric field inside the physical medium. In a portion of reservoir rock, water may have a large dielectric permittivity that is higher than any associated rock or hydrocarbon fluids within the portion. In particular, water permittivity may depend on a frequency of an electromagnetic wave, water pressure, water temperature, and salinity of the reservoir rock mixture.

Still another type of logging technique includes borehole image logging. For example, borehole image logging may be a type of wireline well logging with various data-processing methods that generate centimeter-scale images of a borehole wall and corresponding rock formations. Moreover, borehole image logging may include optical imaging, acoustic imaging, electrical imaging, and/or methods that draw on both acoustic and electrical imaging techniques using the same logging tool. Optical borehole imaging may use downhole cameras that provides a high-resolution color image of a wellbore. Acoustic borehole imaging may use borehole televiewers or ultrasonic borehole imagers that operate with pulsed acoustic energy, e.g., through short bursts of acoustic energy emitted by a rotating transducer in pulse-echo mode. Electrical borehole imaging may use microresistivity devices that include pads and flaps with an array of button electrodes at a predetermined electric potentials, where an applied voltage causes an alternating current to flow from each electrode into the formation and then to return to a specific electrode.

Furthermore, while electromagnetic waves propagate without losing energy in a vacuum, electromagnetic waves in porous reservoir rocks are attenuated and phase shifted during transmission through the rock medium. Porosity measurements from various logs (e.g., density log, neutron long, sonic long, or an NM/R log) may estimate the total porosity in reservoir rocks. In contrast, a multi-frequency dielectric logging tool may determine a value of the water-filled porosity in the reservoir rock.

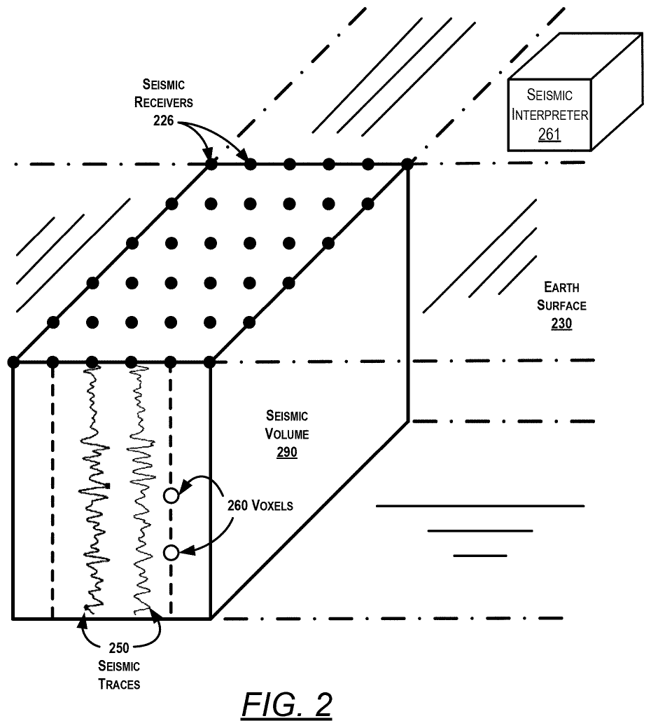

Further referring to FIG. 2, a system in accordance with some implementations of the present disclosure illustrates a seismic volume 290 that includes various seismic traces (e.g., seismic data 178, seismic traces 250) acquired by seismic receivers 226 distributed on various locations on the earth's surface 230. More specifically, the seismic volume 290 may be a three-dimensional cubic data set of seismic traces. Individual cubic cells within the seismic volume 290 may be referred to as voxels or volumetric pixels (e.g., voxels 260). In particular, different portions of a seismic trace may correspond to various depth points within a volume of earth. To generate the seismic volume 290, a three-dimensional array of seismic receivers 226 are disposed along the earth's surface 230 and capable of acquiring seismic data in response to various pressure waves emitted by seismic sources.

Furthermore, seismic data may refer to time domain data that is acquired from a seismic survey (e.g., acquired seismic data may result in the seismic volume 290). However, seismic data may also refer to data acquired over different periods of time, such as in cases where seismic surveys are repeated to obtain time-lapse data. Seismic data may also refer to various seismic attributes derived in response to processing acquired seismic data. In some implementations, seismic data may also refer to depth data. For example, seismic data may be processed, e.g., using a seismic inversion operation, to generate a velocity model of a subterranean formation, or a migrated seismic image of a rock formation within the earth's surface.

While seismic traces with zero offset are generally illustrated in FIG. 2, seismic traces may be stacked, migrated and/or used to generate an attribute volume derived from the underlying seismic traces. For example, an attribute volume may be a dataset where the seismic volume undergoes one or more processing techniques, such as amplitude-versus-offset (AVO) processing. In AVO processing, seismic data may be classified based on reflected amplitude variations due to the presence of hydrocarbon accumulations in a subsurface formation. With an AVO approach, seismic attributes of a subsurface interface may be determined from the dependence of the detected amplitude of seismic reflections on the angle of incidence of the seismic energy. This AVO processing may determine both a normal incidence coefficient of a seismic reflection, and/or a gradient component of the seismic reflection. Likewise, seismic data may be processed according to a pressure wave's apex. With respect to the seismic interpreter 261, a seismic interpreter 261 may include a processor and hardware and/or software with functionality for interpreting, processing, and/or acquiring seismic data. In some embodiments, a seismic interpreter 261 is a component within a reservoir properties estimator (e.g., reservoir properties estimator 160).

In FIG. 1, geosteering may be used to position the drill bit or drill string of the drilling system 110 relative to a boundary between different subsurface layers (e.g., overlying, underlying, and lateral layers of a pay zone) during drilling operations. In particular, measuring rock properties during drilling may provide the drilling system 110 with the ability to steer the drill bit in the direction of desired hydrocarbon concentrations. As such, a geosteering system may use various sensors located inside or adjacent to the drilling string to determine different rock formations within a well path. In some geosteering systems, drilling tools may use resistivity or acoustic measurements to guide the drill bit during horizontal or lateral drilling.

The reservoir properties estimator 160 may include hardware and/or software with functionality to apply more or more ML algorithms 162 (e.g., an unsupervised ML algorithm, a supervised ML algorithm, a DL algorithm) for generating one or more ML models 170 for use in analyzing the formation 106. For example, the reservoir properties estimator 160 may store the encoded data set (e.g., reflectance data 172, rock type data 174, geomechanical property data 176, acoustic velocity data 180 and permeability data 182). In some implementations, the encoded data same may be partitioned into a training data set, a validation data set and a testing data set. The reservoir properties estimator 160 can train a first multiclass model 170 using a DL algorithm (e.g., convolutional neural network (CNN)) based on the training data set to classify rock type of the testing data set. The reservoir properties estimator 160 can train a second model 170 using a DL algorithm (e.g., CNN) based on the training data set to predict permeability of the testing data set. The reservoir properties estimator 160 can train a third model 170 using a DL algorithm (e.g., CNN) based on the training data set to predict sound speed of the testing data set. The reservoir properties estimator 160 can train a fourth model 170 using a DL algorithm (e.g., CNN) based on the training data set to predict geomechanical property (e.g., stiffness) of the testing data set. The reservoir properties estimator 160 can train a fifth model 170 using a DL algorithm (e.g., CNN) based on the training data set and other input data (geological models 164, well logs 166, seismic data 178 and core image/CT/density data 184) to apply a three-dimensional (3D) interpolation and extrapolation of formation properties of the testing data set. Thus, different types of ML models may be trained, such as CNNs, deep neural networks, recurrent neural networks, support vector machines, decision trees, inductive learning models, deductive learning models, supervised learning models, etc. In some embodiments, the reservoir properties estimator 160 may generate augmented or synthetic data to produce a large amount of interpreted data for training a particular model.

Implementations may incorporate a neural network that includes one or more hidden layers, where a hidden layer includes one or more neurons. A neuron may be a modelling node or object that is loosely patterned on a neuron of the human brain. In particular, a neuron may combine data inputs with a set of coefficients, i.e., a set of network weights for adjusting the data inputs. These network weights may amplify or reduce the value of a particular data input, thereby assigning an amount of significance to various data inputs for a task being modeled. Through machine learning, a neural network may determine which data inputs should receive greater priority in determining one or more specified outputs of the neural network. Likewise, these weighted data inputs may be summed such that this sum is communicated through a neuron's activation function to other hidden layers within the neural network. As such, the activation function may determine whether and to what extent an output of a neuron progresses to other neurons where the output may be weighted again for use as an input to the next hidden layer.

In FIG. 1, a well path of a wellbore 104 may be updated by the control system 114 using a geological model (e.g., one of the geological models 175). For example, a control system 114 may communicate geosteering commands to the drilling system 110 based on well data updates that are further adjusted by the reservoir properties estimator 160 using a geological model. As such, the control system 114 may generate one or more control signals for drilling equipment based on an updated well path design and/or a geological model. In some implementations, the reservoir properties estimator 160 can determine one or more formation top depths from seismic data and/or well log data. The reservoir properties estimator 160 may use these formation top depths to adjust the well path of the wellbore 104 accordingly.

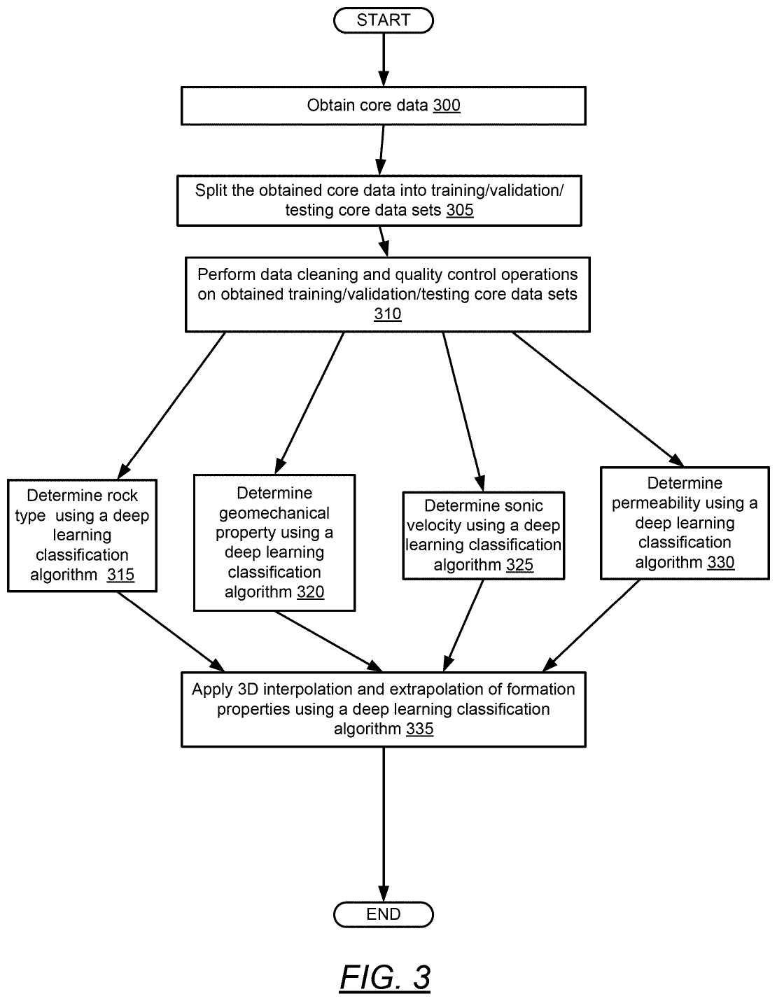

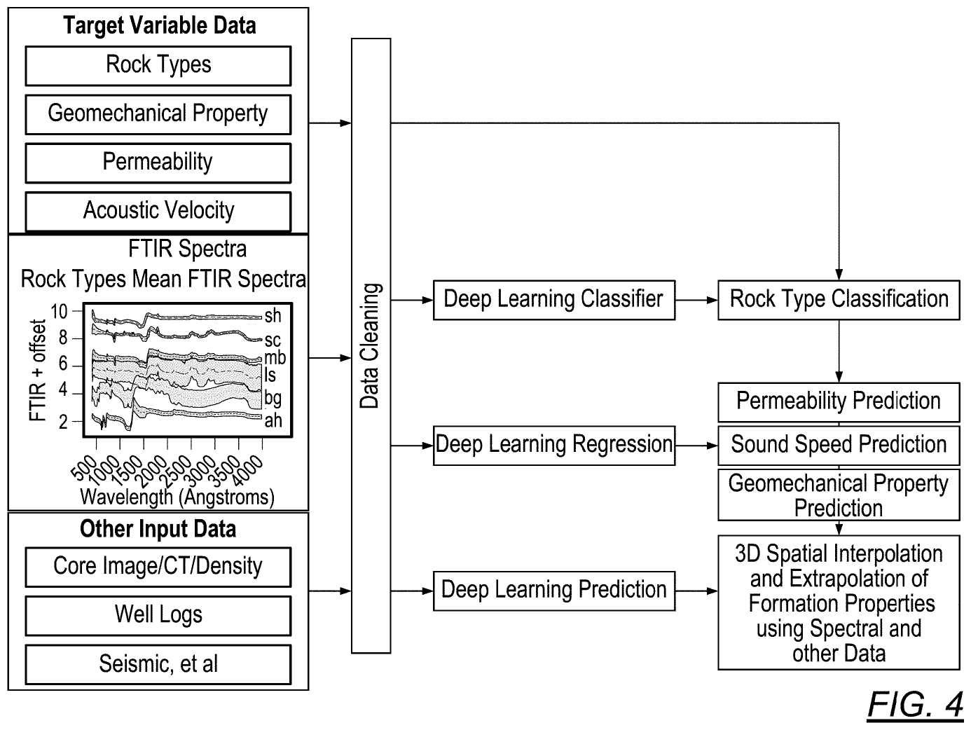

Further referring to FIG. 3, a flowchart in accordance with some implementations of the present disclosure outlines a general method for 3D spatial interpolation and extrapolation of high resolution reservoir properties using machine learning. Examples of reservoir properties can include: rock type, geomechanical property, sonic velocity, and permeability.

The method may initially obtain core data which can include related core information, such as a type of core facies and/or one or predetermined rock types associated with a core specimen. For example, the reservoir properties estimator 160 may attach a label to a core specimen that indicates the rock type as one of a plurality of rock types: (1) a “berea grey sandstone” type (e.g., the label “BG” and the value “0”), (2) a “limestone” type (e.g., the label “L S” and the value “1”), (3) a “shale (carboniferous)” type (e.g., the “SH” label and the value “2”), (4) a “shale (calcium carbonate)” type (e.g., the label “SC” and the value “3”), (5) an “anhydrite” type (e.g., the label “AH” and the value “4”), and (6) a “marble” type (e.g., the label “MB” and the value “5”). An example of the rock type with labels may be found in Table 1 below.

TABLE 1
An example of rock type for analysis

| Label | Rock type | Value |
|---|---|---|
| BG | Berea grey sandstone | 0 |
| LS | Limestone | 1 |
| SH | Shale (carboniferous) | 2 |
| SC | Scale (calcium carbonate) | 3 |
| AH | Anhydrite | 4 |
| MB | Marble (carbonate) | 5 |

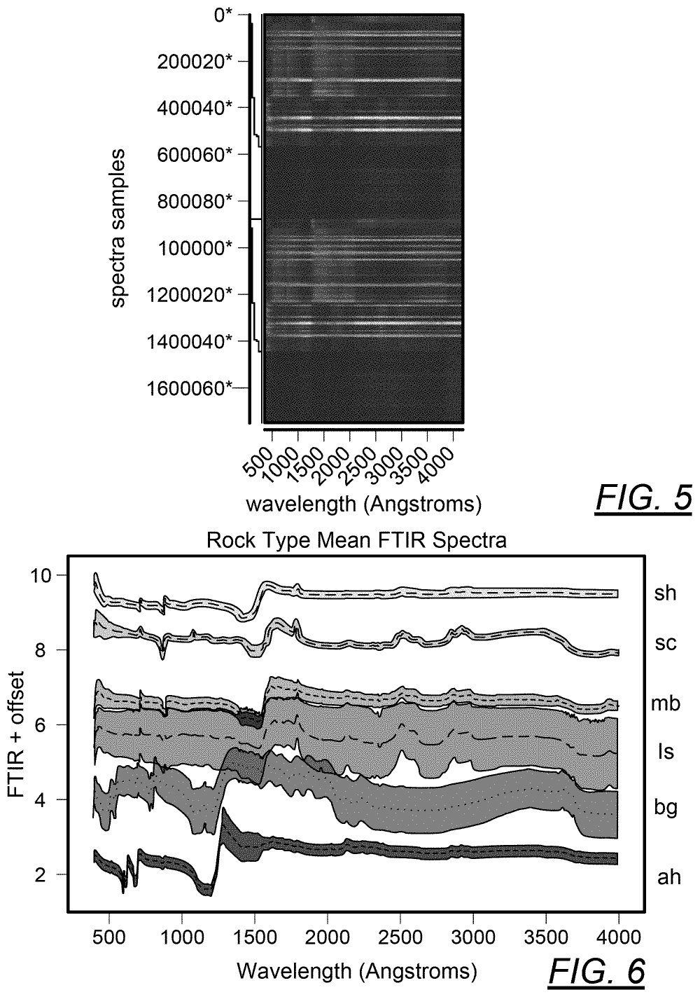

The reservoir properties estimator 160 may import core photographs and other digital images 184 that are converted into depth-indexed image logs. In some cases, core data may include IR reflectance 172 over a broad spectral range of wavenumber 400-4000 cm⁻¹ using a non-contacting FTIR spectroscopy with a measurement spot size ˜3 mm. Likewise, core data may include point-based core plug measurements such as petrophysical properties (e.g., grain density 184, porosity, permeability 182, geochemical properties (e.g., amount of kerogen and total organic carbon in a sample), and/or geomechanical properties (e.g., values of Poisson's ratio or Young's modulus, mechanical stiffness 176, Vp and Vs 180). Core data may also include continuous core scans, such as gamma ray scans, TOC profiling and Computed Tomography (CT) scans 184. Core data may also include log scans and/or ultrasonic data 184 based on measurements performed on a core sample. FIG. 5 shows an example of the FTIR spectrum for a set of core samples. FIG. 6 shows an example of the mean FTIR spectrum and standard deviation for a plurality of rock types (e.g., “SH”, “SC”, “MB”, “LS”, “BG” and “AH”).

The reservoir properties estimator 160 may then split the encoded core data set into training, validation, and testing data sets (305). Examples of training and validation data sets may include: the spectroscopy data (e.g., the IR reflectance data 172), the rock type data 174, the geomechanical data 176, the permeability data 182 and the acoustic velocity data 180 collected from core samples, as well as other input data such as core images/CT/density data 184, well logs 166, and geophysical data (e.g., geological models (164) and seismic data (178)). Examples of testing data may include: the spectroscopy data (e.g., the IR reflectance data 172). By way of illustration, some data splitting techniques may consider 70% of the encoded data set for model training (e.g., tuning of the model parameters), 10% of the encoded data set for validation (e.g., performance validation for each different set of model parameters), and 20% of the encoded data set for testing the final trained model. However, the data split technique may result in the over-fitting problem of the ML models with limited generalization capabilities. For example, the deployed model will underperform when predicting unseen samples.

Next, the reservoir properties estimator 160 may apply data cleaning and quality control operations to the encoded core data sets split into the training data set, the validation data set, the testing data set (310). For example, the reservoir properties estimator 160 may apply range criteria to each types of data to remove out-of-range samples, after removing missing or Not a Number (NaN) data entries. The reservoir properties estimator 160 may apply various statistical outlier detection algorithms to remove outlier samples given that all these measurements are for physical quantities with expected value ranges. The reservoir properties estimator 160 may apply Savitzky-Golay filtering (SC), Kubelka-Munk (K-M) spectral correction in diffuse reflectance, and first derivative (1st D) analysis to pre-process thousands of features with varying amplitudes of the hyperspectral data (e.g., IR reflectance data 172). In addition, the reservoir properties estimator 160 may identify features of significance and reduce dimensionality by applying normalization and dimensionality reduction techniques (e.g., Fisher's linear discriminant analysis (LDA), maximum information coefficient, principal component analysis (PCA), and t-Distributed Stochastic Neighbor Embedding (tSNE)).

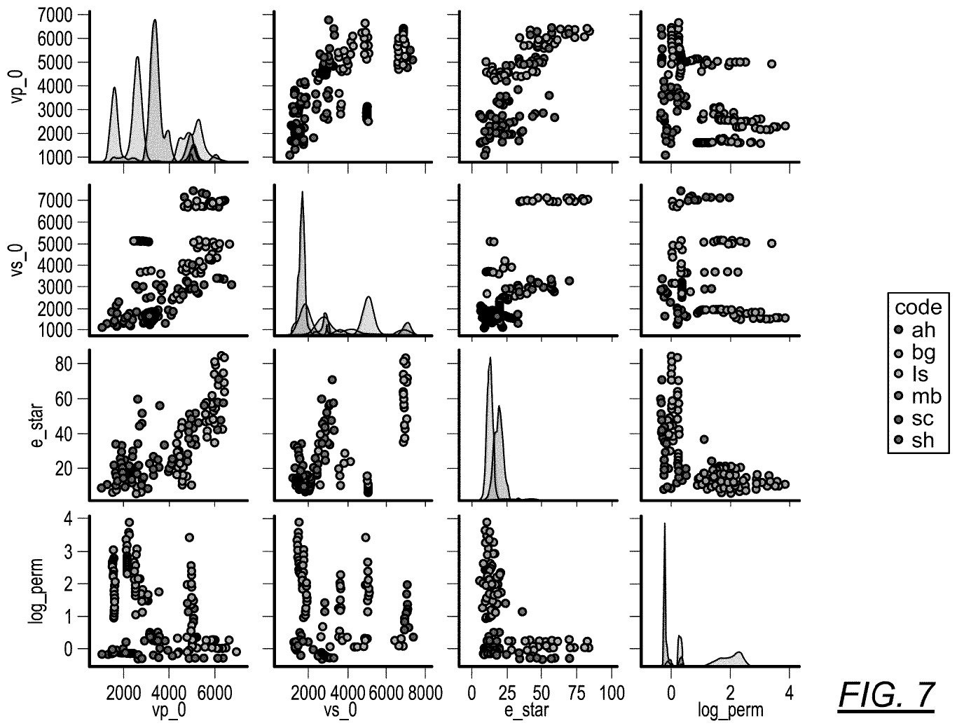

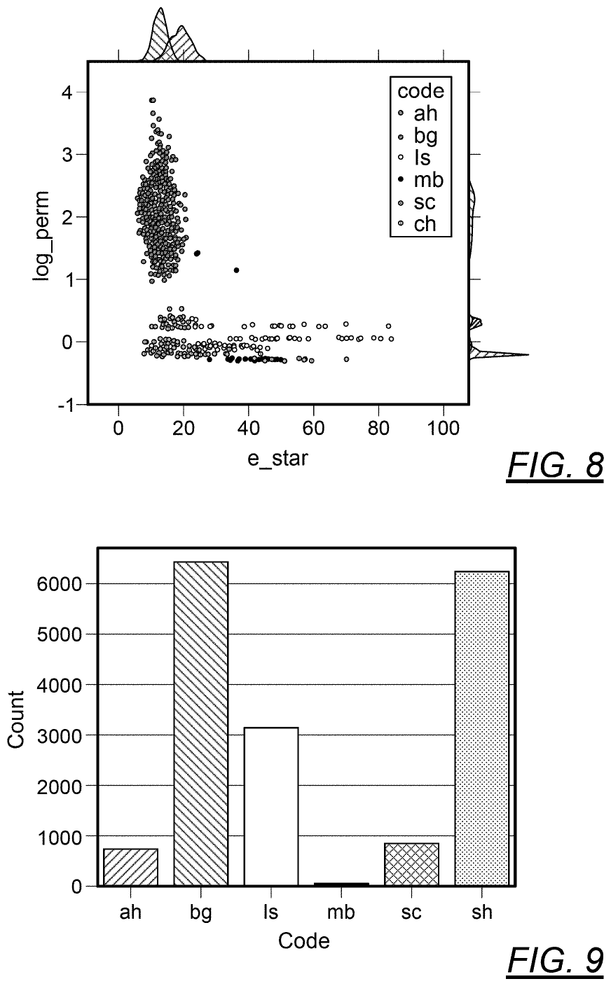

By way illustration, the reservoir properties estimator 160 may apply a cross plot to detect and visualize the data quality for the encoded core data sets (e.g., the training data set, the validation data set, the testing data set) after data cleaning. For example, a cross plot describes a specialized chart to compare multiple measurements made at a single time or location along two or more axes. The axes of the cross plot may be linear or logarithmic. Outliers or samples with value way out of the bounds can cause the distribution in the cross plot to be skewed. FIG. 7 shows an example of the cross plot for all the training data set (e.g., Vp versus Vs, Vp versus logarithmic permeability, Vp versus stiffness, Vs versus logarithmic permeability, Vs versus stiffness, stiff versus logarithmic permeability) color coded by rock type after data cleaning. FIG. 8 shows another example of the cross plot of stiffness and logarithmic permeability for all the training data set color coded by rock type after data cleaning. FIG. 9 shows yet another example of the distribution of the number of core data for a plurality of rock types after data cleaning. As illustrated in FIGS. 7-9, cross fitting can provide clues of the data quality.

Next, in block 315, 320, 325, and/or 330, the reservoir properties estimator 160 may apply one or more ML algorithms (e.g., a CNN) to train and validate five ML models using the training and validation data sets and, based on results of the five ML models, classify or predict formation properties.

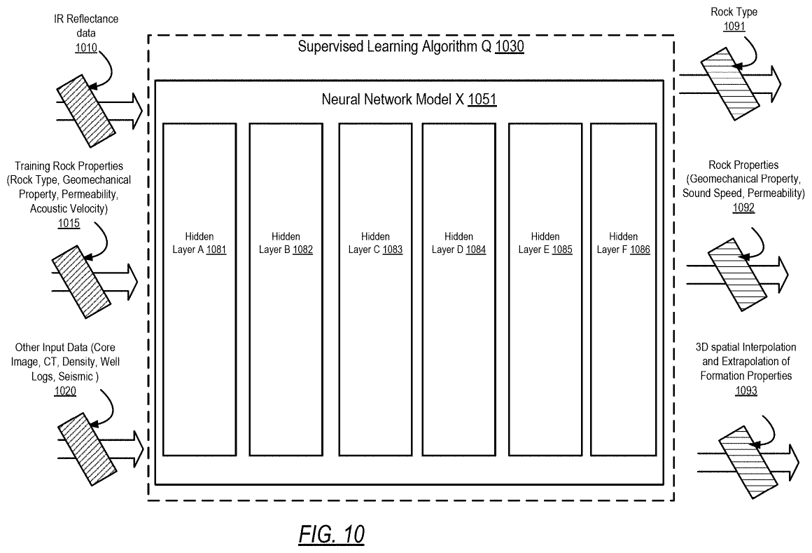

Further referring to FIG. 10, a DL model according to an example can predict rock type 1091, rock properties (e.g., geomechanical property, sound speed, and permeability) 1092 and 3D spatial interpolation and extrapolation of formation properties 1093. In this example, a neural network model X 1051 can be trained by a supervised learning algorithm Q 1030 for predicting various rock type 1091, rock properties (e.g., geomechanical property, sound speed, and permeability) 1092 and 3D spatial interpolation and extrapolation of formation properties 1093. In particular, the neural network model X 1051 includes six hidden layers, namely, hidden layer A 1081, hidden layer B 1082, hidden layer C 1083, hidden layer D 1084, hidden layer E 1085, hidden layer F 1086. Each layer may be a combination of one or more of: convolutional layer, a pooling layer, a rectified linear unit (ReLU) layer, a softmax layer, a regressor layer, and a dropout layer. These hidden layers can be arranged in any order as long as they satisfy the input/output size criteria. Each layer comprises of a set number of image filters. The output of filters from each layer is stacked together in the third dimension. This filter response stack then serves as the input to the next layer(s).

In the illustrated example, the hidden layer A 1081 and the hidden layer B 1082 may be down-sampling blocks to extract high-level features from the input data set. The hidden layer D 1084 and the hidden layer E 1085 may be up-sampling blocks to output the classified or predicted output data set. The hidden layer C 1083 may perform residual stacking as bottleneck between down-sampling blocks (e.g., hidden layer A 1081, hidden layer B 1082) and up-sampling blocks (e.g., hidden layer D 1084, hidden layer E 1085). The hidden layer F 1086 may include a softmax layer or a regressor layer to classify or predict a predetermined class or a value based on input attributes.

In some configurations, the neural network model X 1051 obtains three different input variables for predicting outputs. Examples of input variables may include: IR reflectance data 1010, training rock properties 1015, and other input data 1020. Examples of training rock properties may include rock type, geomechanical property, permeability, and acoustic velocity. Other input data may include: core image, CT, density, well logs, seismic. However, other embodiments are contemplated that use other input variables, such as core scans, seismic data, core image data, data that has been preprocessed with a quality control operation.

In configurations involving a convolutional layer, the input data set may be convolved with a set of learned filters to highlight specific characteristics of the input data set. For example, a pooling layer can produces a scaled down version of the output. This is achieved by considering small neighborhood regions and applying the desired operation filter (e.g. min, max, mean, etc.) across the neighborhood. A ReLU layer can enhance the nonlinear property of the network by introducing a non-saturating activation function. One illustrative example of such a function is set negative values in a response to zero. A fully connected layer provides a high-level reasoning by connecting each node in the layer to all activation nodes in the previous layer. A softmax layer maps the inputs from the previous layer into a value between 0 and 1 which allows for interpreting the outputs as probabilities and selection of classified facie with highest probability. A dropout layer offers a regularization technique for reducing network over-fitting on the training data by dropping out individual nodes with a certain probability. A loss layer (utilized in training) defines the weight dependent cost function that needs to be optimized (bring cost down to zero) for improved accuracy.

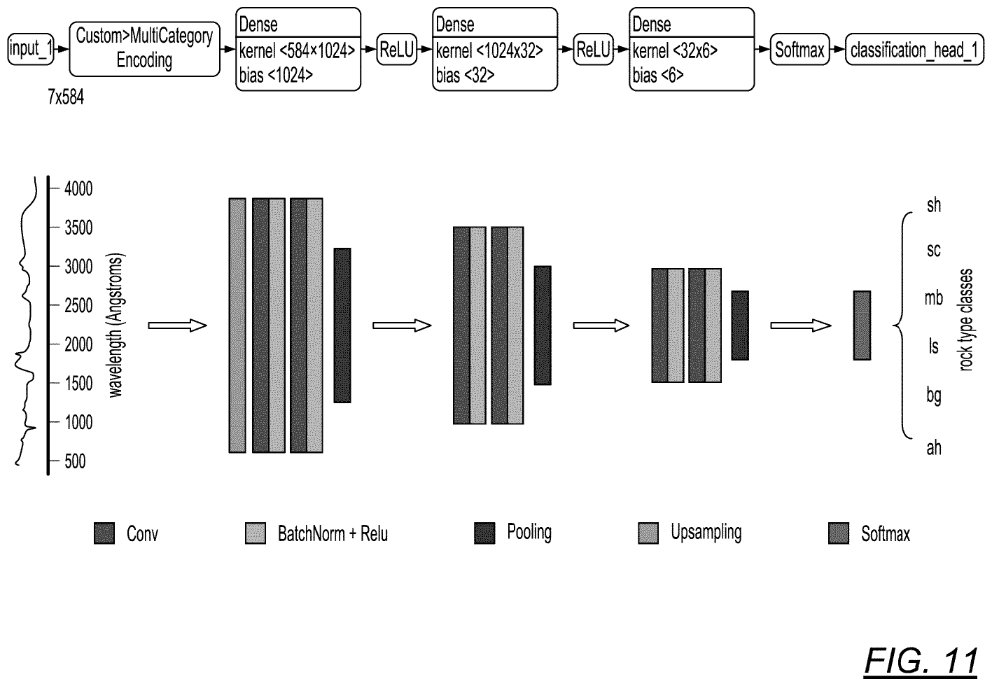

In block 315, the reservoir properties estimator 160 may train a first multiclass ML model using a supervised ML algorithm (e.g., a CNN) based on the training data set, and predict a rock type of the testing data set. For example, the supervised ML algorithm may include an artificial neural network, a random forest, a support vector machine, or a CNN. In some configurations, the output of the supervised ML algorithm may be one or more predetermined classes corresponding to a specific rock type or a specific facies type (e.g., “SH”, “SC”, “MB”, “LS”, “BG” and “AH”). FIG. 11 shows an example of the CNN architecture for classifying a plurality of rock types after data cleaning.

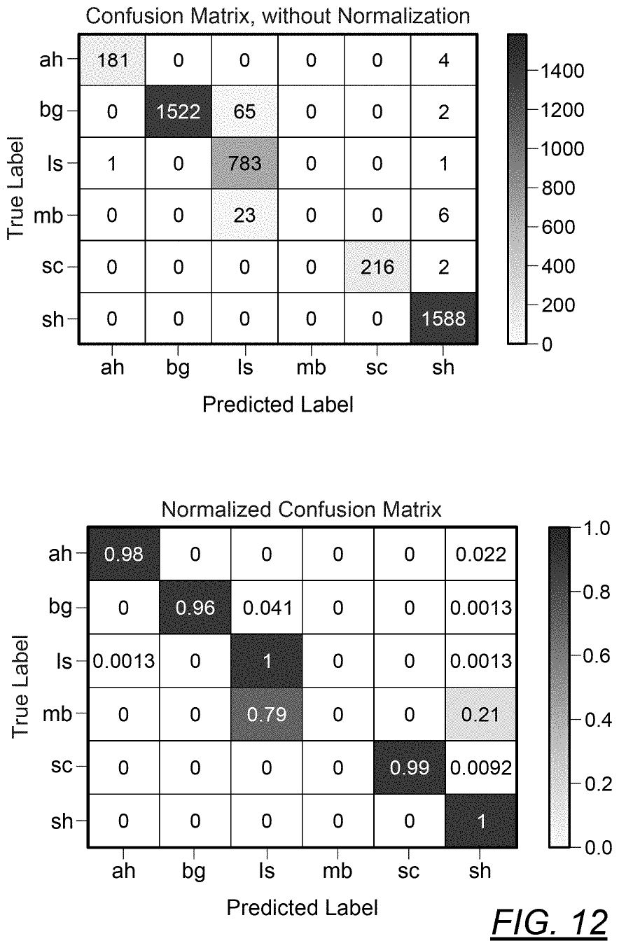

Moreover, the performance of the rock type classification may be evaluated by the normalized or unnormalized confusion matrix which quantifies the inter-class misclassification error. The columns of the confusion matrix correspond to the predicted rock type categories and the rows of the matrix correspond to the actual rock type categories. For example, in the normalized confusion matrix, a value of “1” indicates the predicted rock type categories match the actual rock type categories for all core samples in the testing data set. FIG. 12 shows an example of the confusion matrix for classifying a plurality of rock types after data cleaning.

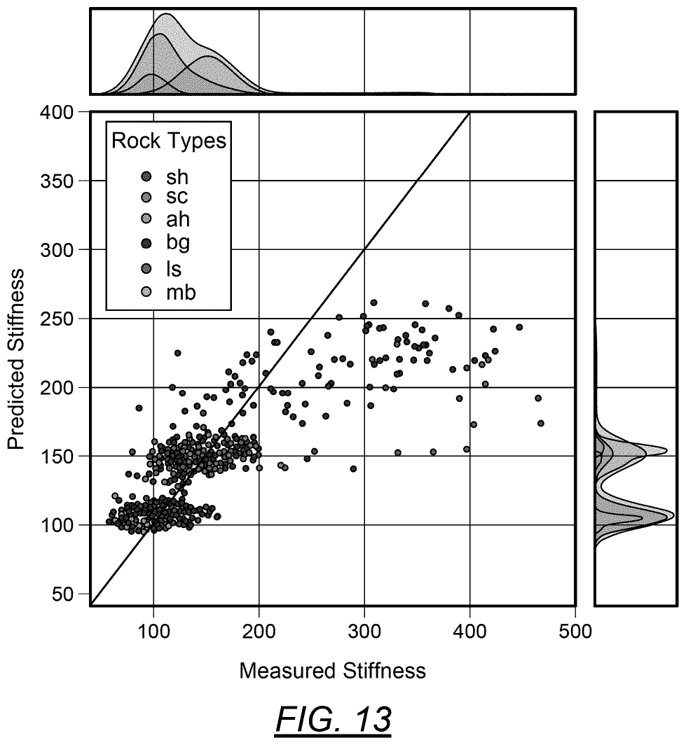

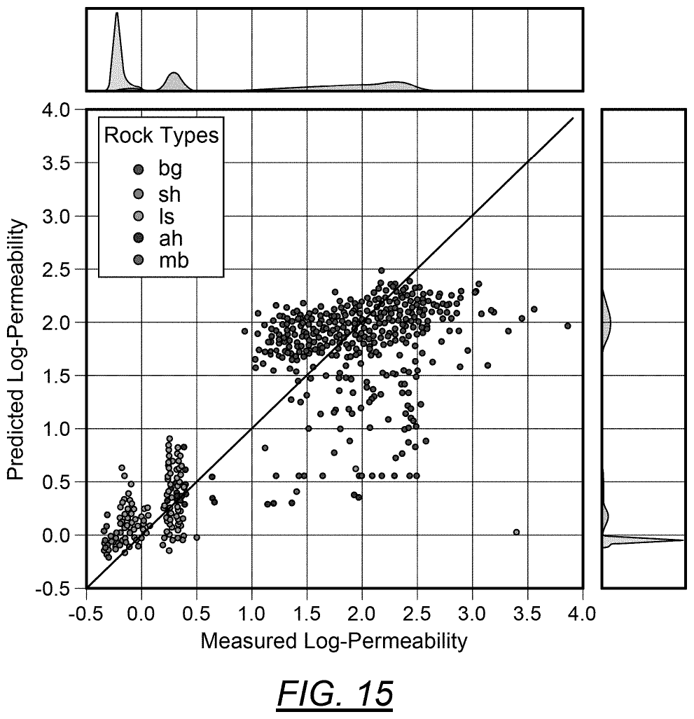

In block 320, the reservoir properties estimator 160 may train a second ML model using a supervised ML algorithm (e.g., a CNN) based on the training data set, and predict a geomechanical property (e.g., stiffness) of the testing data set. The input encoded data set may include the FTIR spectrum and the stiffness measurements after data cleaning. In some implementations, the output of the supervised ML algorithm may be a predicted stiffness value. The performance of the stiffness prediction may be evaluated by the cross plot between the predicted stiffness values and the measured stiffness values for the testing data set. In one example, the stiffness prediction yields acceptable results when the predicted stiffness values deviate from the measured stiffness values within 3 standard deviations of the distribution for all the rock types. In another example, the stiffness prediction yields unsatisfactory results when the predicted stiffness values deviate from the measured stiffness values outside 3 standard deviations of the distribution for all the rock types. FIG. 13 shows an example of the cross plot for predicted stiffness values and measured stiffness values for a plurality of rock types.

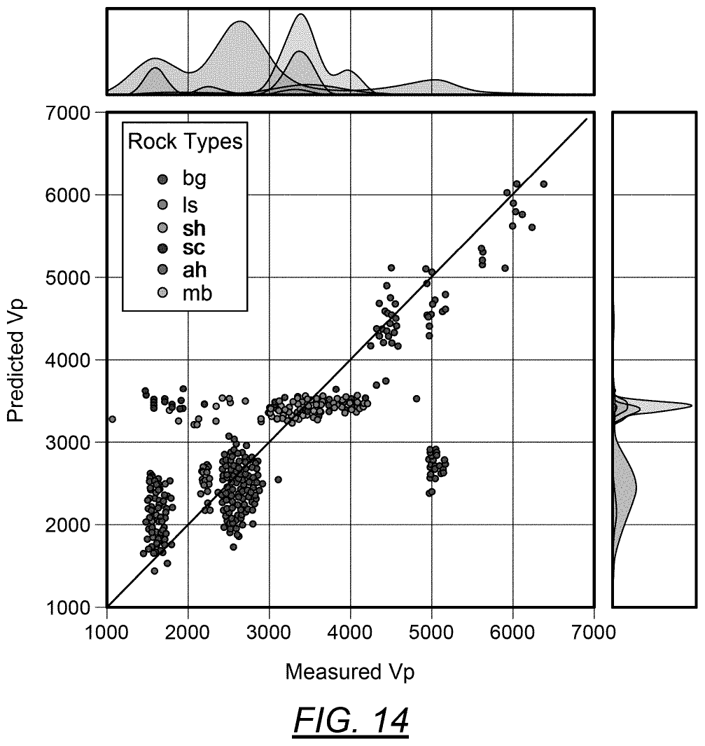

In block 325, the reservoir properties estimator 160 may train a third ML model using a supervised ML algorithm (e.g., a CNN) based on the training data set, and predict a sonic velocity (e.g., Vp and/or Vs) of the testing data set. The input encoded data set can include the FTIR spectrum and the sonic velocity measurements after data cleaning. In some implementations, the output of the supervised ML algorithm may be a predicted sonic velocity (e.g., Vp and/or Vs) value which provides a valuable bridge from the core scale to the well log scale, with high resolution. The performance of the sonic velocity prediction may be evaluated by the cross plot between the predicted sonic velocity values and the measured sonic velocity values for the testing data set. In one example, the sonic velocity prediction yields acceptable results if the predicted sonic velocity values deviate from the measured sonic velocity values within 3 standard deviations of the distribution for all the rock types. In another example, the sonic velocity prediction yields unsatisfactory results when the predicted sonic velocity values deviate from the measured sonic velocity values outside 3 standard deviations of the distribution for all the rock types. FIG. 14 shows an example of the cross plot for predicted Vp values and measured Vp values for a plurality of rock types.

In block 330, the reservoir properties estimator 160 may train a fourth ML model using a supervised ML algorithm (e.g., a CNN) based on the training data set, and predict a permeability of the testing data set. The input encoded data set can include the FTIR spectrum and the permeability measurements (e.g., logarithmic permeability) after data cleaning. In some configurations, the output of the supervised ML algorithm may be a predicted logarithmic permeability value. The performance of the logarithmic permeability prediction may be evaluated by the cross plot between the predicted logarithmic permeability values and the measured logarithmic permeability values for the testing data set. In one example, the logarithmic permeability prediction yields acceptable results when the predicted logarithmic permeability values deviate from the measured logarithmic permeability values within 3 standard deviations of the distribution for all the rock types. In another example, the logarithmic permeability prediction yields unsatisfactory results when the predicted permeability values deviate from the measured logarithmic permeability values outside 3 standard deviations of the distribution for all the rock types. FIG. 15 shows an example of the cross plot for predicted logarithmic permeability values and measured logarithmic permeability values for a plurality of rock types.

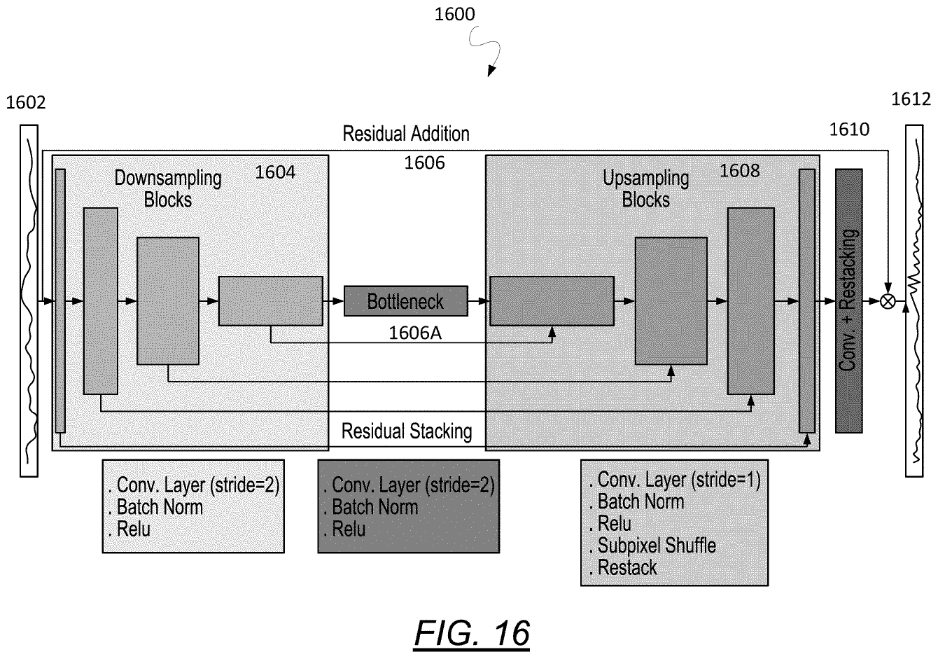

In block 335, the reservoir properties estimator 160 may train a fifth ML model using a supervised ML algorithm (e.g., a CNN) to apply 3D spatial interpolation and extrapolation of formation properties based on measurements from multiple wells and models from blocks 315, 320, 325, and 330. The input encoded data set can include the predicted rock type, permeability, sonic velocity and geomechanical property (e.g., stiffness) from spectroscopic data (e.g., the FTIR spectrum). The “high spatial resolution” reservoir properties derived from core samples (spectroscopic or others) can be associated with high spatial and spectral resolution, but are typically limited in spatial coverage. Such “high spatial resolution” reservoir properties can be populated using additional measurements covering larger area/volume, but potentially at lower resolution, such as well logs and geophysical surveys (e.g. seismic, EM et al). Through interpolation or extrapolation, the depth coverage of the high resolution data can be extended. In some configurations, the output of the supervised ML algorithm may include a predicted formation property value at core scale for the depth range of the input well log data (e.g., sonic log, density, etc.). In some configurations, the predicted high resolution formation properties may be extrapolated to inter-well spaces. FIG. 16 shows an example of a diagram 1600 for the DL model to map the coarse resolution well log data (e.g., sonic log, density, etc.) to high resolution core scale formation properties. Input data 1602 may include coarse resolution well log data (e.g., sonic log, density, etc.) Input data 1602 may be processed by downsampling blocks 1604 including, for example, a convolution layer, a rectified linear unit (ReLU) layer, a batch normalization (Batch Norm) layer. Here, the batch normalization layer may apply a normalization of the input with respect to one or more of all available feature spaces. Thereafter, the residual addition block 1606 may form bottleneck 1606A where downsampling stops and upsampling starts. Bottleneck 1606A may include, for example, a convolution layer, a rectified linear unit (ReLU) layer, a batch normalization (Batch Norm) layer. Subsequently, upsampling blocks 1608 may lead to convolution and restacking block 1610 to generate output data with a spatial resolution comparable to spectroscopic data, such as FTIR data. Upsampling blocks 1608 may include, for example, a convolution layer, a batch normalization layer, a rectified linear unit (ReLU) layer. Upsampling blocks 1608 may further include subpixel shuffle, and restacking.

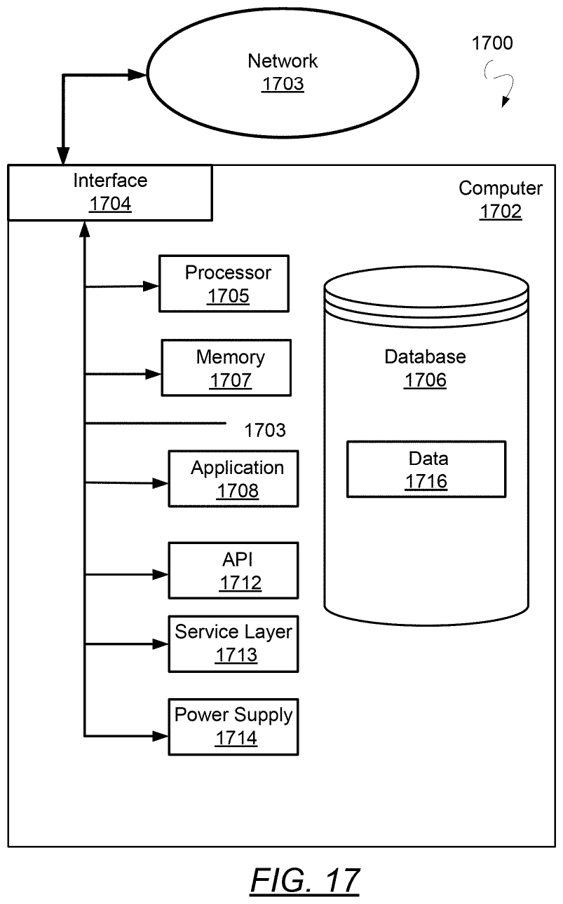

FIG. 17 is a block diagram illustrating an example of a computer system 600 used to provide computational functionalities associated with described algorithms, methods, functions, processes, flows, and procedures, according to an implementation of the present disclosure. The illustrated computer 1702 is intended to encompass any computing device such as a server, desktop computer, laptop/notebook computer, wireless data port, smart phone, personal data assistant (PDA), tablet computing device, one or more processors within these devices, another computing device, or a combination of computing devices, including physical or virtual instances of the computing device, or a combination of physical or virtual instances of the computing device. Additionally, the computer 1702 can comprise a computer that includes an input device, such as a keypad, keyboard, touch screen, another input device, or a combination of input devices that can accept user information, and an output device that conveys information associated with the operation of the computer 1702, including digital data, visual, audio, another type of information, or a combination of types of information, on a graphical-type user interface (UI) (or GUI) or other UI.

The computer 1702 can serve in a role in a computer system as a client, network component, a server, a database or another persistency, another role, or a combination of roles for performing the subject matter described in the present disclosure. The illustrated computer 1702 is communicably coupled with a network 1703. In some implementations, one or more components of the computer 1702 can be configured to operate within an environment, including cloud-computing-based, local, global, another environment, or a combination of environments.

The computer 1702 is an electronic computing device operable to receive, transmit, process, store, or manage data and information associated with the described subject matter. According to some implementations, the computer 1702 can also include or be communicably coupled with a server, including an application server, e-mail server, web server, caching server, streaming data server, another server, or a combination of servers.

The computer 1702 can receive requests over network 1703 (for example, from a client software application executing on another computer 1702) and respond to the received requests by processing the received requests using a software application or a combination of software applications. In addition, requests can also be sent to the computer 1702 from internal users, external or third-parties, or other entities, individuals, systems, or computers.

Each of the components of the computer 1702 can communicate using a system bus 1703. In some implementations, any or all of the components of the computer 1702, including hardware, software, or a combination of hardware and software, can interface over the system bus 1703 using an application programming interface (API) 1712, a service layer 1713, or a combination of the API 1712 and service layer 1713. The API 1712 can include specifications for routines, data structures, and object classes. The API 1712 can be either computer-language independent or dependent and refer to a complete interface, a single function, or even a set of APIs. The service layer 1713 provides software services to the computer 1702 or other components (whether illustrated or not) that are communicably coupled to the computer 1702. The functionality of the computer 1702 can be accessible for all service consumers using this service layer. Software services, such as those provided by the service layer 1713, provide reusable, defined functionalities through a defined interface. For example, the interface can be software written in JAVA, C++, another computing language, or a combination of computing languages providing data in extensible markup language (XML) format, another format, or a combination of formats. While illustrated as an integrated component of the computer 1702, alternative implementations can illustrate the API 1712 or the service layer 1713 as stand-alone components in relation to other components of the computer 1702 or other components (whether illustrated or not) that are communicably coupled to the computer 1702. Moreover, any or all parts of the API 1712 or the service layer 1713 can be implemented as a child or a sub-module of another software module, enterprise application, or hardware module without departing from the scope of the present disclosure.

The computer 1702 includes an interface 1704. Although illustrated as a single interface 1704 in FIG. 17, two or more interfaces 1704 can be used according to particular needs, desires, or particular implementations of the computer 1702. The interface 1704 is used by the computer 1702 for communicating with another computing system (whether illustrated or not) that is communicatively linked to the network 1703 in a distributed environment. Generally, the interface 1704 is operable to communicate with the network 1703 and comprises logic encoded in software, hardware, or a combination of software and hardware. More specifically, the interface 1704 can comprise software supporting one or more communication protocols associated with communications such that the network 1703 or interface's hardware is operable to communicate physical signals within and outside of the illustrated computer 1702.

The computer 1702 includes a processor 1705. Although illustrated as a single processor 1705 in FIG. 17, two or more processors can be used according to particular needs, desires, or particular implementations of the computer 1702. Generally, the processor 1705 executes instructions and manipulates data to perform the operations of the computer 1702 and any algorithms, methods, functions, processes, flows, and procedures as described in the present disclosure.

The computer 1702 also includes a database 1706 that can hold data for the computer 1702, another component communicatively linked to the network 1703 (whether illustrated or not), or a combination of the computer 1702 and another component. For example, database 1706 can be an in-memory, conventional, or another type of database storing data consistent with the present disclosure. In some implementations, database 1706 can be a combination of two or more different database types (for example, a hybrid in-memory and conventional database) according to particular needs, desires, or particular implementations of the computer 1702 and the described functionality. Although illustrated as a single database 1706 in FIG. 17, two or more databases of similar or differing types can be used according to particular needs, desires, or particular implementations of the computer 1702 and the described functionality. While database 1706 is illustrated as an integral component of the computer 1702, in alternative implementations, database 1706 can be external to the computer 1702. As illustrated, the database 1706 holds the previously described data 1716 including, for example, multiple streams of data from various sources, such as the training data, the validation data, and the testing data.

The computer 1702 also includes a memory 1707 that can hold data for the computer 1702, another component or components communicatively linked to the network 1703 (whether illustrated or not), or a combination of the computer 1702 and another component. Memory 1707 can store any data consistent with the present disclosure. In some implementations, memory 1707 can be a combination of two or more different types of memory (for example, a combination of semiconductor and magnetic storage) according to particular needs, desires, or particular implementations of the computer 1702 and the described functionality. Although illustrated as a single memory 1707 in FIG. 17, two or more memories 1707 or similar or differing types can be used according to particular needs, desires, or particular implementations of the computer 1702 and the described functionality. While memory 1707 is illustrated as an integral component of the computer 1702, in alternative implementations, memory 1707 can be external to the computer 1702.

The application 1708 is an algorithmic software engine providing functionality according to particular needs, desires, or particular implementations of the computer 1702, particularly with respect to functionality described in the present disclosure. For example, application 1708 can serve as one or more components, modules, or applications. Further, although illustrated as a single application 1708, the application 1708 can be implemented as multiple applications 1708 on the computer 1702. In addition, although illustrated as integral to the computer 1702, in alternative implementations, the application 1708 can be external to the computer 1702.

The computer 1702 can also include a power supply 1714. The power supply 1714 can include a rechargeable or non-rechargeable battery that can be configured to be either user- or non-user-replaceable. In some implementations, the power supply 1714 can include power-conversion or management circuits (including recharging, standby, or another power management functionality). In some implementations, the power-supply 1714 can include a power plug to allow the computer 1702 to be plugged into a wall socket or another power source to, for example, power the computer 1702 or recharge a rechargeable battery.

There can be any number of computers 1702 associated with, or external to, a computer system containing computer 1702, each computer 1702 communicating over network 1703. Further, the term “client,” “user,” or other appropriate terminology can be used interchangeably, as appropriate, without departing from the scope of the present disclosure. Moreover, the present disclosure contemplates that many users can use one computer 1702, or that one user can use multiple computers 1702.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs, that is, one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal, for example, a machine-generated electrical, optical, or electromagnetic signal that is generated to encode information for transmission to a receiver apparatus for execution by a data processing apparatus. The computer-storage medium can be a machine-readable storage device, a machine-readable storage substrate, a random or serial access memory device, or a combination of computer-storage mediums. Configuring one or more computers means that the one or more computers have installed hardware, firmware, or software (or combinations of hardware, firmware, and software) so that when the software is executed by the one or more computers, particular computing operations are performed.

The term “real-time,” “real time,” “realtime,” “real (fast) time (RFT),” “near(ly) real-time (NRT),” “quasi real-time,” or similar terms (as understood by one of ordinary skill in the art), means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second (s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

The terms “data processing apparatus,” “computer,” or “electronic computer device” (or equivalent as understood by one of ordinary skill in the art) refer to data processing hardware and encompass all kinds of apparatus, devices, and machines for processing data, including by way of example, a programmable processor, a computer, or multiple processors or computers. The apparatus can also be, or further include special purpose logic circuitry, for example, a central processing unit (CPU), an FPGA (field programmable gate array), or an ASIC (application-specific integrated circuit). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with an operating system of some type, for example LINUX, UNIX, WINDOWS, MAC OS, ANDROID, IOS, another operating system, or a combination of operating systems.

A computer program, which can also be referred to or described as a program, software, a software application, a unit, a module, a software module, a script, code, or other component can be written in any form of programming language, including compiled or interpreted languages, or declarative or procedural languages, and it can be deployed in any form, including, for example, as a stand-alone program, module, component, or subroutine, for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files, for example, files that store one or more modules, sub-programs, or portions of code. A computer program can be deployed to be executed on one computer or on multiple computers that are located at one site or distributed across multiple sites and interconnected by a communication network.

While portions of the programs illustrated in the various figures can be illustrated as individual components, such as units or modules, that implement described features and functionality using various objects, methods, or other processes, the programs can instead include a number of sub-units, sub-modules, third-party services, components, libraries, and other components, as appropriate. Conversely, the features and functionality of various components can be combined into single components, as appropriate. Thresholds used to make computational determinations can be statically, dynamically, or both statically and dynamically determined.

Described methods, processes, or logic flows represent one or more examples of functionality consistent with the present disclosure and are not intended to limit the disclosure to the described or illustrated implementations, but to be accorded the widest scope consistent with described principles and features. The described methods, processes, or logic flows can be performed by one or more programmable computers executing one or more computer programs to perform functions by operating on input data and generating output data. The methods, processes, or logic flows can also be performed by, and apparatus can also be implemented as, special purpose logic circuitry, for example, a CPU, an FPGA, or an ASIC.

Computers for the execution of a computer program can be based on general or special purpose microprocessors, both, or another type of CPU. Generally, a CPU will receive instructions and data from and write to a memory. The essential elements of a computer are a CPU, for performing or executing instructions, and one or more memory devices for storing instructions and data. Generally, a computer will also include, or be operatively coupled to, receive data from or transfer data to, or both, one or more mass storage devices for storing data, for example, magnetic, magneto-optical disks, or optical disks. However, a computer need not have such devices. Moreover, a computer can be embedded in another device, for example, a mobile telephone, a personal digital assistant (PDA), a mobile audio or video player, a game console, a global positioning system (GPS) receiver, or a portable memory storage device.

Non-transitory computer-readable media for storing computer program instructions and data can include all forms of media and memory devices, magnetic devices, magneto optical disks, and optical memory device. Memory devices include semiconductor memory devices, for example, random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Magnetic devices include, for example, tape, cartridges, cassettes, internal/removable disks. Optical memory devices include, for example, digital video disc (DVD), CD-ROM, DVD+/−R, DVD-RAM, DVD-ROM, HD-DVD, and BLURAY, and other optical memory technologies. The memory can store various objects or data, including caches, classes, frameworks, applications, modules, backup data, jobs, web pages, web page templates, data structures, database tables, repositories storing dynamic information, or other appropriate information including any parameters, variables, algorithms, instructions, rules, constraints, or references. Additionally, the memory can include other appropriate data, such as logs, policies, security or access data, or reporting files. The processor and the memory can be supplemented by, or incorporated in, special purpose logic circuitry.

To provide for interaction with a user, implementations of the subject matter described in this specification can be implemented on a computer having a display device, for example, a CRT (cathode ray tube), LCD (liquid crystal display), LED (Light Emitting Diode), or plasma monitor, for displaying information to the user and a keyboard and a pointing device, for example, a mouse, trackball, or trackpad by which the user can provide input to the computer. Input can also be provided to the computer using a touchscreen, such as a tablet computer surface with pressure sensitivity, a multi-touch screen using capacitive or electric sensing, or another type of touchscreen. Other types of devices can be used to interact with the user. For example, feedback provided to the user can be any form of sensory feedback. Input from the user can be received in any form, including acoustic, speech, or tactile input. In addition, a computer can interact with the user by sending documents to and receiving documents from a client computing device that is used by the user.

The term “graphical user interface,” or “GUI,” can be used in the singular or the plural to describe one or more graphical user interfaces and each of the displays of a particular graphical user interface. Therefore, a GUI can represent any graphical user interface, including but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server, or that includes a front-end component, for example, a client computer having a graphical user interface or a Web browser through which a user can interact with an implementation of the subject matter described in this specification, or any combination of one or more such back-end, middleware, or front-end components. The components of the system can be interconnected by any form or medium of wireline or wireless digital data communication (or a combination of data communication), for example, a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) using, for example, 802.11 a/b/g/n or 802.20 (or a combination of 802.11x and 802.20 or other protocols consistent with the present disclosure), all or a portion of the Internet, another communication network, or a combination of communication networks. The communication network can communicate with, for example, Internet Protocol (IP) packets, Frame Relay frames, Asynchronous Transfer Mode (ATM) cells, voice, video, data, or other information between networks addresses.

The computing system can include clients and servers. A client and server are generally remote from each other and typically interact through a communication network. The relationship of client and server arises by virtue of computer programs running on the respective computers and having a client-server relationship to each other.

While this specification contains many specific implementation details, these should not be construed as limitations on the scope of what can be claimed, but rather as descriptions of features that can be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations can be considered optional), to achieve desirable results. In certain circumstances, multitasking or parallel processing (or a combination of multitasking and parallel processing) can be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

What is claimed is:

1. A computer-implemented method comprising:
accessing a plurality of geo-exploration data from a first drilling site, wherein the plurality of geo-exploration data include spectroscopic infra-red (IR) data, wherein at least portions of the plurality of geo-exploration data are based on measurements of core samples taken from the first drilling site;
based on, at least in part, the plurality of geo-exploration data including the spectroscopic IR data, training a set of deep learning models, each deep learning model comprising multiple layers and configured to predict one or more geological formation properties;
applying the set of deep learning models to newly received geo-exploration data that also includes spectroscopic IR data; and
predicting the one or more geological formation properties based on, at least in part, the newly received geo-exploration data.

2. The computer-implemented method of claim 1, wherein the spectroscopic IR data includes Fourier Transform Infrared Spectroscopy (FTIR) data of core samples at the drilling site, and wherein the newly received geo-exploration data are from a second drilling site different from the first drilling site.

3. The computer-implemented method of claim 2, wherein the set of deep learning models include a first deep learning model configured to predict a rock type of the core samples, and wherein training the first deep learning model includes training based on, at least in part, the FTIR data of the core samples from the first drilling site.

4. The computer-implemented method of claim 2, wherein the set of deep learning models include a second deep learning model configured to predict a geomechanical property of the core samples, and wherein training the second deep learning model includes training based on, at least in part, the FTIR data of the core samples at first the drilling site.

5. The computer-implemented method of claim 2, wherein the set of deep learning models include a third deep learning model configured to predict a sonic velocity of the core samples, and wherein training the third deep learning includes training based on, at least in part, the FTIR data of the core samples at the first drilling site.

6. The computer-implemented method of claim 2, wherein the set of deep learning models include a fourth deep learning model configured to predict a permeability of the core samples, and wherein training the fourth deep learning includes training based on, at least in part, the FTIR data of the core samples at the first drilling site.

7. The computer-implemented method of claim 1, further comprising:
validating the set of deep learning models by cross correlating predicted values of the one or more geological formation properties with measured values of the one or more geological formation properties.

8. The computer-implemented method of claim 1, wherein at least one deep learning model from the set of deep learning models is trained predict a geological formation property with a spatial resolution that is higher than well logs in the plurality of geo-exploration data.

9. The computer-implemented method of claim 1, wherein the set of deep learning model each comprises a layer of one or more convolutional neural network (CNN) blocks.

10. The computer-implemented method of claim 9, wherein the layer of one or more CNN blocks are followed by a softmax layer or a regressor layer, wherein the softmax layer is configured to generate a classification as a geological formation property, and wherein the regressor layer is configured to quantify a value of a geological formation property.

11. A computer system comprising one or more processors configured to perform operations of:
accessing a plurality of geo-exploration data from a first drilling site, wherein the plurality of geo-exploration data include spectroscopic infra-red (IR) data, wherein at least portions of the plurality of geo-exploration data are based on measurements of core samples taken from the first drilling site;
based on, at least in part, the plurality of geo-exploration data including the spectroscopic IR data, training a set of deep learning models, each deep learning model comprising multiple layers and configured to predict one or more geological formation properties;
applying the set of deep learning models to newly received geo-exploration data that also includes spectroscopic IR data; and
predicting the one or more geological formation properties based on, at least in part, the newly received geo-exploration data.

12. The computer system of claim 11, wherein the spectroscopic IR data includes Fourier Transform Infrared Spectroscopy (FTIR) data of core samples at the drilling site, and wherein the newly received geo-exploration data are from a second drilling site different from the first drilling site.

13. The computer system of claim 12, wherein the set of deep learning models include a first deep learning model configured to predict a rock type of the core samples, and wherein training the first deep learning model includes training based on, at least in part, the FTIR data of the core samples from the first drilling site.

14. The computer system of claim 12, wherein the set of deep learning models include a second deep learning model configured to predict a geomechanical property of the core samples, and wherein training the second deep learning model includes training based on, at least in part, the FTIR data of the core samples at first the drilling site.

15. The computer system of claim 12, wherein the set of deep learning models include a third deep learning model configured to predict a sonic velocity of the core samples, and wherein training the third deep learning includes training based on, at least in part, the FTIR data of the core samples at the first drilling site.

16. The computer system of claim 12, wherein the set of deep learning models include a fourth deep learning model configured to predict a permeability of the core samples, and wherein training the fourth deep learning includes training based on, at least in part, the FTIR data of the core samples at the first drilling site.

17. The computer system of claim 11, wherein the operations further comprise:
validating the set of deep learning models by cross correlating predicted values of the one or more geological formation properties with measured values of the one or more geological formation properties.

18. The computer system of claim 11, wherein at least one deep learning model from the set of deep learning models is trained predict a geological formation property with a spatial resolution that is higher than well logs in the plurality of geo-exploration data.

19. The computer system of claim 11, wherein the set of deep learning model each comprises a layer of one or more convolutional neural network (CNN) blocks.

20. The computer system of claim 19, wherein the layer of one or more CNN blocks are followed by a softmax layer or a regressor layer, wherein the softmax layer is configured to generate a classification as a geological formation property, and wherein the regressor layer is configured to quantify a value of a geological formation property.
